(19) United States
(12) Patent Application Publication
(10) Pub. No.: US 2021/0367211 A1
(43) Pub. Date: Nov. 25, 2021

(54) ORGANIC LIGHT-EMITTING DEVICE AND METHOD OF MANUFACTURING THE SAME

(71) Applicant: Wuhan China Star Optoelectronics Semiconductor Display Technology Co., Ltd,, Wuhan, Hubei (CN)

(72) Inventor: Jiulin Shen, Wuhan, Hubei (CN)

(21) Appl. No.: 16/499,620

(22) PCT Filed: Jun. 27, 2019
(86) PCT No.: PCT/CN2019/093302

§ 371 Date: Sep. 30, 2019

(30) Foreign Application Priority Data
Apr. 19, 2019 (CN) 201910319925.5

(51) Int. Cl. H01L 51/52

(52) U.S. Cl. CPC H01L 51/5275; H01L 51/56; H01L 51/5253; H01L 51/5246

(57) ABSTRACT

An OLED device includes a substrate, a transistor layer, OLEDs for emitting light with various wavelengths, a first cover layer, a second cover layer, and a third cover layer arranged on an OLED emitting light of a third wavelength. A thickness of the first cover layer is equal to

$$\frac{{λ}_{1}}{4 \times Δ n ( {λ}_{1} )} ,$$

a thickness of the second cover layer is equal to

$$\frac{{λ}_{2}}{4 \times Δ n ( {λ}_{2} )} ,$$

and a thickness of the third cover layer is equal to

$$\frac{{λ}_{3}}{4 \times Δ n ( {λ}_{2} )} ,$$

where λ₁ indicates the first wavelength, λ₂ indicates the second wavelength, λ₃ indicates the third wavelength, Δn(λ₁) indicates a birefringence of the light of the first wavelength λ₁ passing through the first cover layer, Δn(λ₂) indicates a birefringence of the light of the second wavelength λ₂ passing through the second cover layer, and Δn(λ₃) indicates a birefringence of the light of the third wavelengths λ₃ passing through the third cover layer.

### BACKGROUND

### 1. Field of the Disclosure

The present disclosure relates to the field of display technology, and more particularly, to an organic light-emitting diode (OLED) device and a method of manufacturing the OLED.

### 2. Description of the Related Art

An OLED features light weight, self-illumination, wide viewing angles, low driving voltage, high luminous efficiency, low power consumption, and swift response speed. Owing to these features, the OLED is applied more widely. In particular, a flexible OLED display device is characteristic of being bendable and easily portable, and has become the mainstream in the field of display development. However, the organic light-emitting material for the OLED display device is easily deteriorated due to the entry of outside air and moisture. To prevent deterioration of the OLED display device due to infiltration of outside air or moisture, a thin film encapsulation method that an organic layer and an inorganic layer are alternately laminated has been developed. The thin film can be applied to a flexible, ultra-thin OLED display device.

However, an OLED device in the form of top emitting is generally equipped with an anode with high reflectivity, which may form a micro-cavity structure with the semi-reflective cathode to achieve the purpose of improving the light extraction rate and narrowing the spectrum of the device. However, such an anode with highly reflectivity causes the panel of a lower contrast ratio under high-intensity ambient light illumination, which negatively affects the user's viewing the image. To avoid the interference of external ambient light on the OLED display, the surface of the display is attached to a circular polarizer necessarily. However, the thickness of the OLED panel is increased with the circular polarizer, affecting and limiting the yield rate of the OLED display and increasing the production cost. The efficiency of the OLED display device is lowered, and the thickness is increased, which is disadvantageously applied to a flexible display.

### SUMMARY

An object of the present disclosure is to propose an organic light-emitting device (OLED) device to deal with the problem of the related art as mentioned above.

According a first aspect of the present disclosure, an organic light-emitting diode (OLED) device includes a substrate, a transistor layer arranged on the substrate, a plurality of OLEDs for emitting light with various wavelengths, a first cover layer arranged on an OLED emitting light of a first wavelength, a second cover layer, arranged on an OLED emitting light of a second wavelength, and a third cover layer arranged on an OLED emitting light of a third wavelength. A thickness of the first cover layer, a thickness of the second cover layer, a thickness of the third cover layer are different from one another. Each of the plurality of OLEDs comprises an anode layer, a cathode layer and a light-emitting layer therebetween.

According an embodiment of the present disclosure, the OLED device further comprises a linear polarizer arranged on the first cover layer, the second cover layer, and the third cover layer and is configured to linearly deflect the light emitted from the first cover layer, the light emitted from the second cover layer, and the light emitted from the third cover layer.

According an embodiment of the present disclosure, the OLED device further comprises a cover protective layer, a pressure sensitive adhesive and a protective film. The cover protective layer is arranged on the first cover layer, the second cover layer, and the third cover layer. The pressure sensitive adhesive is configured to bond the cover protective layer to the linear polarizer. The protective film for the linear polarizer is arranged on the linear polarizer.

According an embodiment of the present disclosure, the first cover layer, the second cover layer, and the third cover layer are made of an anisotropic material.

According an embodiment of the present disclosure, the thickness of the first cover layer is equal to λ₁/4×Δn(λ₁); the thickness of the second cover layer is equal to λ₂/4×Δn(λ₂); the thickness of the third cover layer is equal to λ₃/4×Δn(λ₃), where λ₁ indicates the first wavelength, λ₂ indicates the second wavelength, λ₃ indicates the third wavelength, Δn(λ₁) indicates a birefringence of the light of the first wavelength λ₁ passing through the first cover layer, Δn(λ₂) indicates a birefringence of the light of the second wavelength λ₂ passing through the second cover layer, and Δn(λ₃) indicates a birefringence of the light of the third wavelengths λ₃ passing through the third cover layer.

According an embodiment of the present disclosure, the first wavelength ranges from 620 nm to 750 nm, the second wavelength ranges from 495 nm to 570 nm, and the third wavelength ranges from 450 nm to 495 nm.

According an embodiment of the present disclosure, the birefringence of the first cover layer, the birefringence of the second cover layer, and the birefringence of the third cover layer are between 0.005 and 0.02.

According a first aspect of the present disclosure, a method of manufacturing an organic light-emitting diode (OLED) device comprises: forming a transistor layer on a substrate; forming a plurality of OLEDs on the plurality of transistor layers to emit light with various wavelengths, wherein each of the plurality of OLEDs comprises an anode layer, a cathode layer, and a light-emitting layer arranged therebetween and is configured to generate light according to a data voltage; and forming a first cover layer arranged on an OLED emitting light of a first wavelength, a second cover layer arranged on an OLED emitting light of a second wavelength, and a third cover layer arranged on an OLED emitting light of a third wavelength, wherein a thickness of the first cover layer, a thickness of the second cover layer, a thickness of the third cover layer are different from one another.

According an embodiment of the present disclosure, the thickness of the first cover layer is equal to

$$\frac{{λ}_{1}}{4 \times Δ n ( {λ}_{1} )} \text{;}$$

the thickness of the second cover layer is equal to

$$\frac{{λ}_{2}}{4 \times Δ n ( {λ}_{2} )} \text{;}$$

thickness of the third cover layer is equal to

$$\frac{{λ}_{3}}{4 \times Δ n ( {λ}_{2} )} ,$$

where λ₁ indicates the first wavelength, λ₂ indicates the second wavelength, λ₃ as indicates the third wavelength, Δn(λ₁) indicates a birefringence of the light of the first wavelength λ₁ passing through the first cover layer, Δn(λ₂) indicates a birefringence of the light of the second wavelength λ₂ passing through the second cover layer, and Δn(λ₃) indicates a birefringence of the light of the third wavelengths λ₃ passing through the third cover layer.

According an embodiment of the present disclosure the step of forming a first cover layer arranged on an OLED emitting light of a first wavelength, a second cover layer arranged on an OLED emitting light of a second wavelength, and a third cover layer arranged on an OLED emitting light of a third wavelength, comprises a step of: depositing the first cover layer arranged on the OLED emitting light of the first wavelength, the second cover layer arranged on the OLED emitting light of the second wavelength, and the third cover layer arranged on the OLED emitting light of the third wavelength, by thermal evaporation, sputtering, inkjet printing, or chemical vapor deposition.

Compared with the related art, a first cover layer, a second cover layer, and a third cover layer of different thicknesses are deposited on a plurality of OLEDs device of different wavelengths, respectively, in the OLED device proposed by the present disclosure. The thickness of each of the cover layers is determines according to the wavelength of the light emitted by the corresponding OLED and the amount of birefringence of the light emitted by the corresponding OLED. In this way, the combination of each cover layer and the linear polarizer can function as a circular polarizer of the related art. Moreover, the circular deviation effect that can be achieved in the corresponding wavelength range avoids color shift. It is not necessary to use a circular polarizer, either. The thickness of the OLED panel is not affected. The production cost is reduced as well.

### BRIEF DESCRIPTION OF THE DRAWINGS

FIG. 1 illustrates a schematic diagram of an organic light-emitting diode (OLED) device according to a first embodiment of the present disclosure.

FIG. 2 is a circuit diagram of a pixel circuit in an active area as illustrated in FIG. 1.

FIG. 3 illustrates a schematic diagram of the OLED device according to the present embodiment of the present disclosure.

FIG. 4 illustrates a flowchart of a method of manufacturing an OLED device as illustrated in FIG. 3.

### DESCRIPTION OF THE EMBODIMENTS

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

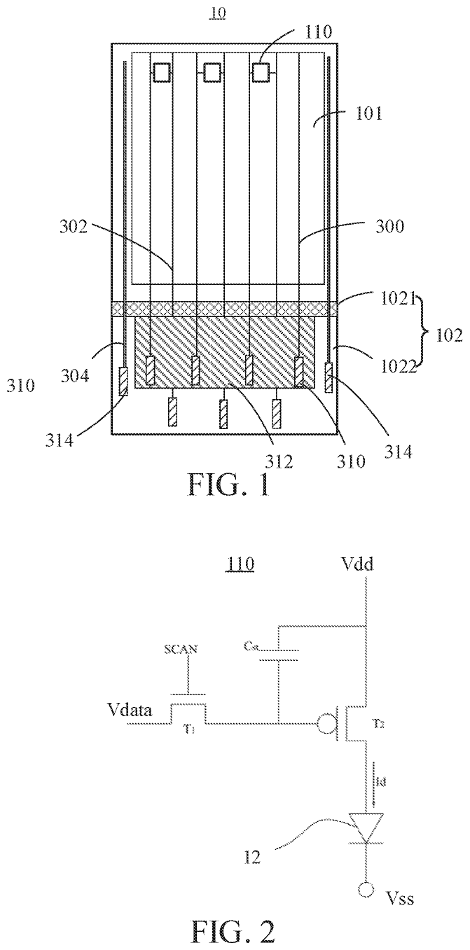

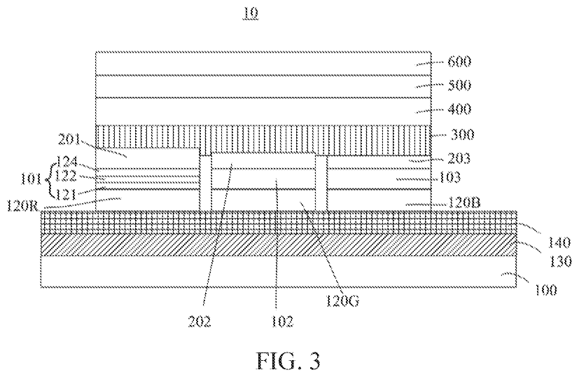

Please refer to FIG. 1 and FIG. 2. FIG. 1 illustrates a schematic diagram of an organic light-emitting diode (OLED) device according to a first embodiment of the present disclosure. FIG. 2 is a circuit diagram of a pixel circuit 110 in an active area 101 as illustrated in FIG. 1. The flexible OLED device 10 includes the active area 101 and a non-active area 102. The non-active area 102 includes a bendable area 1021 and a signal pad area 1022. The bendable region 1021 can be bent such that the signal pad area 1022 is arranged on the back side of the display screen, thereby shortening the bezel. A plurality of data voltage leads 300, a plurality of driving voltage leads 302, 304, a plurality of data transferring pads 310, and a plurality of driving transferring pads 312, 314 are distributed in the signal pad area 1022. The plurality of data voltage leads 300 are connected one-to-one to the plurality of data transferring pads 310. The plurality of driving voltage leads 302, 304 are connected one-to-one to the plurality of driving transferring pads 312, 314. A plurality of pixel circuits 110 are arranged in the active area 101. Each of the pixel circuits 110 is connected to the corresponding driving voltage leads 302, 304 and the data voltage lead 300. The data transferring pad 310 is configured to receive a data voltage Vdata transmitted by an image processor (not illustrated) and transmit the data voltage Vdata to the corresponding pixel circuit 110 via the data voltage lead 300. The driving transferring pads 312, 314 are configured to transfer high/low level driving voltages Vdd/Vss, respectively, and transmit the driving voltages Vdd/Vss to the corresponding pixel circuit 110 via the driving voltage leads 302, 304.

The pixel circuit 110 includes a switching transistor T₁, a driving transistor T₂, a storage capacitor Cst, and an OLED 12. When the scanning signal voltage is passed to turn on the switching transistor T₁ via a scanning terminal SCAN, the data voltage Vdata is sent via the data terminal DATA and transmitted to a gate of the driving transistor T₂ via the switching transistor T₁. When the driving transistor T₂ operates in a saturation regain, the conductive current Id of the driving transistor T₂ is determined by the voltage difference Vsg across a gate of the driving transistor T₂ and a source of the driving transistor T₂. Vsg is equal to Vdd−Vdata (Vsg=Vdd−Vdata). That is, Id=K(Vsg−Vt)²=K(Vdd−Vdata−Vt)² stands. Since the emitting luminance of the OLED 12 is proportional to the conductive current Id, the OLED 12 adjusts the emitting luminance according to the data voltage Vdata so that the corresponding pixels can generate different grayscales. Furthermore, the data voltage Vdata is stored in the storage capacitor Cst so that the luminance of the OLED 12 can be retained while the image changes.

Please refer to FIG. 3 illustrating a schematic diagram of the OLED device 10 according to the present embodiment of the present disclosure. Thin film transistor (TFT) layers 120R, 120G, 120B are formed on the substrate 100. The OLEDs 101, 102, 103 are disposed on the TFT layers 120R, 120G, 120B, and electrically connected to the TFT layers 120R, 120G, 120B. The substrate 100 is made of a bendable insulating material, for example, a polymeric material such as polyimide (PI), polycarbonate (PC), polyethylene terephthalate (PET), polyethylene naphthalate (PEN), a polyarylate (PAR), or a glass fiber reinforced plastic (FRP). The surface of the substrate 100 is covered with an inorganic layer 130 and a buffer layer 140 to prevent moisture or impurities from diffusing through the substrate 100. Owing to the inorganic layer 130 and the buffer layer 140, the surface of the substrate 100 is plain. The inorganic layer 130 and the buffer layer 140 may be made of inorganic materials such as silicon oxide (SiOx), silicon nitride (SiNx), silicon oxynitride (SiOxNy), aluminum oxide (AlOx), or aluminum nitride (AlNx) in the present embodiment. The TFT layers 120R, 120G, and 120B are arranged on the buffer layer 140 and configured to drive the OLEDs 101, 102, 103 to emit light of different colors, that is, light of different wavelengths. For example, the OLEDs 101, 102, 103 emit light of a first wavelength λ1 (red light), a second wavelength λ2 (green light), and a third wavelength λ3 (blue light), respectively. The first wavelength λ1 refers to the central wavelength of the red light. The second wavelength λ2 refers to the central wavelength of the green light. The third wavelength λ3 refers to the central wavelength of the blue light. The first TFT layers 120R, 120G, 120B correspond to the transistor T₂ as illustrated in FIG. 2. The OLEDs 101, 102, 103 correspond to the OLED 12 as illustrated in FIG. 2.

The OLEDs 101, 102, 103 are formed on the TFT layers 120R, 120G, 120B. Each of the OLEDs 101, 102, 103 includes an anode layer 121, a light-emitting layer 122, and a cathode layer 124. Only the OLED 101 with the anode layer 121, the light-emitting layer 122, and the cathode layer 124 are illustrated for the user to understand the figures easily. Take the OLED 101 for example. The anode layer 121 is connected to the TFT layer 120R. The anode layer 121, served as a reflective electrode, may be made of Ag, magnesium (Mg), Al, Pt, Pd, Au, Ni, Nd, iridium (Ir), Cr, or a mixture of these materials. Besides, ITO, IZO, ZnO, In₂O₃ or the like may be formed on the reflective electrode (i.e., the anode layer 121). The light-emitting layer 122 is arranged on the anode layer 121. The light-emitting layer 122 may be formed in the process of vapor deposition and may be made of a low molecular organic material or a high molecular organic material. The light-emitting layer 122 includes an organic emission layer, and may further include one or more of a hole injection layer (HIL), a hole transport layer (HTL), an electron transport layer (ETL), and an electron injection layer (EIL). The cathode layer 124 is arranged on the light-emitting layer 122. Similar to the anode layer 121, the cathode layer 124 is a transparent electrode. Since the light-emitting layer 122 is interposed between the anode layer 121 and the cathode layer 124, the anode layer 121 and the cathode layer 124 are insulated from each other. The light-emitting layer 122 emits visible light according to a voltage difference between the anode layer 121 and the cathode layer 124, thereby realizing an image recognizable by the user. Specifically, the cathode layer 124 may be lithium (Li), calcium (Ca), lithium fluoride/calcium (LiF/Ca), lithium fluoride/aluminum (LiF/Al), aluminum (Al), magnesium (Mg) or compound material and can be deposited on the light-emitting layer 122.

The first cover layer 201 is arranged on the OLED 101 emitting the first wavelength λ₁. The thickness of the first cover layer 201 is equal to

$$\frac{{λ}_{1}}{4 \times Δ n ( {λ}_{1} )} .$$

The second cover layer 202 is arranged on the OLED 101 emitting the second wavelength λ₂. The thickness of the second cover layer 202 is equal to

$$\frac{{λ}_{3}}{4 \times Δ n ( {λ}_{2} )} .$$

The third cover layer 203 is arranged on the OLED 101 emitting the third wavelength λ₃. The thickness of the third cover layer 203 is equal to

$$\frac{{λ}_{3}}{4 \times Δ n ( {λ}_{2} )} .$$

Δn(λ₁) indicates the birefringence of the light of the first wavelength λ₁ passing through the first cover layer 201. Δn(λ₂) indicates the birefringence of the light of the second wavelength λ₂ passing through the second cover layer 202. Δn(λ₃) indicates the birefringence of the light of the third wavelengths λ₃ passing through the third cover layer 203. The first cover layer 201, the second cover layer 202, and the third cover layer 203 are deposited on the OLEDs 101, 102, 103 by thermal evaporation, sputtering, inkjet printing, or chemical vapor deposition. In another embodiment, a first cover layer 201, a second cover layer 202, and a third cover layer 203 are made of a transparent anisotropic material such as silicon dioxide. The birefringence of the first cover layer 201, the second cover layer 202, and the third cover layer 203 is between 0.005 and 0.02. In another embodiment, organic light-emitting diodes (OLEDs) 101, 102, 103 emit a red light of a first wavelength λ₁, a green light of a second wavelength λ₂, and a blue light of a third wavelength λ₃, respectively. Specifically, the light of the first wavelength λ₁ indicates red light between 620 nm and 750 nm (nm is the abbreviation for nanometer). The light of the second wavelength λ₂ indicates green light between 495 nm and 570 nm. The light of the third wavelength λ₃ indicates blue light between 450 nm and 495 nm. The wavelength ranges of the first wavelength λ₁, the second wavelength λ₂, and the third wavelength λ₃ include a wavelength range in addition to the wavelength range of the above-mentioned visible light.

The OLED device 10 further includes a cover protective layer 300, a pressure sensitive adhesive 400, a linear polarizer 500, and a protective film 600 for the linear polarizer 500. The cover protective layer 300 is arranged on the first cover layer 201, the second cover layer 202, and the third cover layer 203. The cover protective layer 300 may be made of an organic material such as acryl, polyimide (PI), and benzocyclobutene (BCB). The pressure sensitive adhesive 400 is configured to bond the cover protective layer 300 to the linear polarizer 500. The line polarizer 500 is configured to linearly deflect light emitted from the first cover layer 201, the second cover layer 202, and the third cover layer 203. The protective film 600 is disposed on the linear polarizer 500.

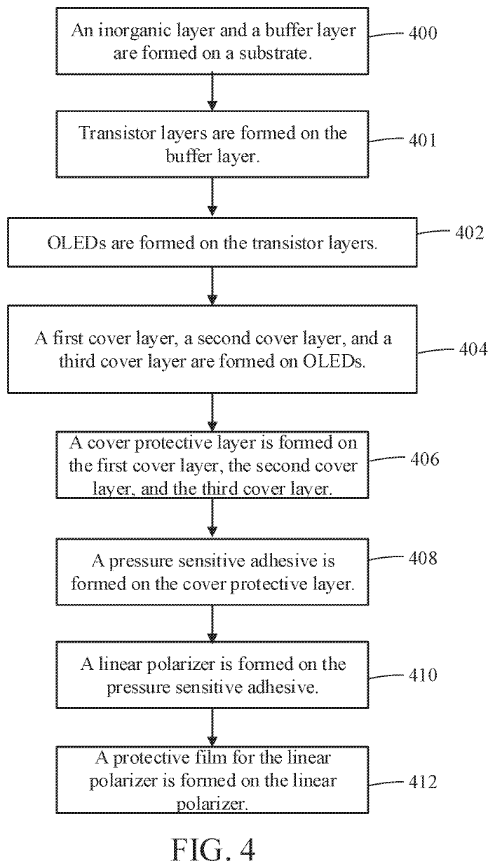

Please refer to FIG. 4 illustrating a flowchart of a method of manufacturing an organic light-emitting diode (OLED) device 10, as illustrated in FIG. 3. The method include block 400, block 401, block 402, block 404, block 406, block 408, block 410, and block 412.

At block 400, an inorganic layer 130 and a buffer layer 140 are formed on a substrate 100.

At block 401, a plurality of transistor layers 120R, 120G, 120B are formed on the buffer layer 140 such that the plurality of transistor layers 120R, 120G, 120B are arranged on the substrate 100.

At block 402, a plurality of OLEDs 101, 102, and 103 are formed on the plurality of transistor layers 120R, 120G, 120B. Each of the OLEDs 101, 102, 103 includes an anode layer 121, a light-emitting layer 122, and a cathode layer 124. The light-emitting layer 122 is arranged between the anode layer 121 and the cathode layer 124 and configured to generate light according to the difference between a voltage imposed on the anode layer 121 and a voltage imposed on the cathode layer 124. The plurality of OLEDs 101, 102, 103 emit a light of a first wavelength λ₁, a light of a second wavelength λ₂, and a light of a third wavelength λ₃, respectively.

At block 404, the first cover layer 201, the second cover layer 202, and the third cover layer 203 are formed on a plurality of OLEDs 101, 102, 103 which emit the light of the first wavelength λ₁, the light of the second wavelength λ₂, and the light of the third wavelength λ₃, respectively. The thicknesses of the first cover layer 201, the thicknesses of the second cover layer 202, the thicknesses of the third cover layer 203 are different from one another. The first cover layer 201, the second cover layer 202, and the third cover layer 203 are made of an anisotropic material such as silicon dioxide. The thickness of the first cover layer 201 is equal to

$$\frac{{λ}_{1}}{4 \times Δ n ( {λ}_{1} )} .$$

The thickness of the second cover layer 202 is equal to

$$\frac{{λ}_{2}}{4 \times Δ n ( {λ}_{2} )} .$$

The thickness of the third cover layer 203 is equal to

$$\frac{{λ}_{2}}{4 \times Δ n ( {λ}_{2} )} .$$

Δn(λ₁) indicates the birefringence of the light of the first wavelength λ₁ passing through the first cover layer 201. Δn(λ₂) indicates the birefringence of the light of the second wavelength λ₂ passing through the second cover layer 202. Δn(λ₃) indicates the birefringence of the light of the third wavelengths λ₃ passing through the third cover layer 203. In this step, the first cover layer 201, the second cover layer 202, and the third cover layer 203 are deposited on the plurality of OLEDs 101, 102, 103 which emit the light of the first wavelength λ₁, the light of the second wavelength λ₂, and the light of the third wavelength λ₃, respectively, by thermal evaporation, sputtering, inkjet printing, or chemical vapor deposition. The birefringence of the first cover layer 201, the second cover layer 202, and the third cover layer 203 is between 0.005 and 0.02.

At block 406, a cover protective layer 300 is formed on the first cover layer 201, the second cover layer 202, and the third cover layer 203.

At block 408, a pressure sensitive adhesive 400 is formed on the cover protective layer 300.

At block 410, a linear polarizer 500 is formed on the pressure sensitive adhesive 400 such that the linear polarizer 500 is arranged on the first cover layer 201, the second cover layer 202, and the third cover layer 203. The linear polarizer 500 is configured to linearly deflect the light emitted from the first cover layer 201, the second cover layer 202, and the third cover layer 203. The pressure sensitive adhesive 400 is configured to bond the cover protective layer 300 to the linear polarizer 500.

At block 412, a protective film 600 for the linear polarizer 500 is formed on the linear polarizer 500.

In conclusion, a first cover layer, a second cover layer, and a third cover layer of different thicknesses are deposited on a plurality of OLEDs device of different wavelengths, respectively, in the OLED device proposed by the present disclosure. The thickness of each of the cover layers is determines according to the wavelength of the light emitted by the corresponding OLED and the amount of birefringence of the light emitted by the corresponding OLED. In this way, the combination of each cover layer and the linear polarizer can function as a circular polarizer of the related art. Moreover, the circular deviation effect that can be achieved in the corresponding wavelength range avoids color shift. It is not necessary to use a circular polarizer, either. The thickness of the OLED panel is not affected. The production cost is reduced as well.

The present disclosure is described in detail in accordance with the above contents with the specific preferred examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

What is claimed is:

1. An organic light-emitting diode (OLED) device, comprising:
a substrate;
a transistor layer, arranged on the substrate;
a plurality of OLEDs for emitting light with various wavelengths, each of the plurality of OLEDs comprising an anode layer, a cathode layer and a light-emitting layer therebetween;
a first cover layer, arranged on an OLED emitting light of a first wavelength;
a second cover layer, arranged on an OLED emitting light of a second wavelength; and
a third cover layer, arranged on an OLED emitting light of a third wavelength;
wherein a thickness of the first cover layer, a thickness of the second cover layer, a thickness of the third cover layer are different from one another.

2. The OLED device of claim 1, further comprising a linear polarizer arranged on the first cover layer, the second cover layer, and the third cover layer and is configured to linearly deflect the light emitted from the first cover layer, the light emitted from the second cover layer, and the light emitted from the third cover layer.

3. The OLED device of claim 2, further comprising:
a cover protective layer, arranged on the first cover layer, the second cover layer, and the third cover layer;
a pressure sensitive adhesive, configured to bond the cover protective layer to the linear polarizer; and
a protective film for the linear polarizer, arranged on the linear polarizer.

4. The OLED device of claim 1, wherein the first cover layer, the second cover layer, and the third cover layer are made of an anisotropic material.

5. The OLED device of claim 1, wherein the thickness of the first cover layer is equal to
$$\frac{{λ}_{1}}{4 \times Δ n ( {λ}_{1} )} ,$$
the thickness of the second cover layer is equal to
$$\frac{{λ}_{3}}{4 \times Δ n ( {λ}_{2} )} ,$$
and the thickness of the third cover layer is equal to
$$\frac{{λ}_{3}}{4 \times Δ n ( {λ}_{2} )} ,$$
where λ₁ indicates the first wavelength, λ₂ indicates the second wavelength, λ₃ indicates the third wavelength, Δn(λ₁) indicates a birefringence of the light of the first wavelength λ₁ passing through the first cover layer, Δn(λ₂) indicates a birefringence of the light of the second wavelength λ₂ passing through the second cover layer, and Δn(λ₃) indicates a birefringence of the light of the third wavelengths λ₃ passing through the third cover layer.

6. The OLED device of claim 5, wherein the first wavelength ranges from 620 nm to 750 nm, the second wavelength ranges from 495 nm to 570 nm, and the third wavelength ranges from 450 nm to 495 nm.

7. The OLED device of claim 5, wherein the birefringence of the first cover layer, the birefringence of the second cover layer, and the birefringence of the third cover layer are between 0.005 and 0.02.

8. A method of manufacturing an organic light-emitting diode (OLED) device, comprising:
forming a transistor layer on a substrate;
forming a plurality of OLEDs on the plurality of transistor layers to emit light with various wavelengths, wherein each of the plurality of OLEDs comprises an anode layer, a cathode layer, and a light-emitting layer arranged therebetween and is configured to generate light according to a data voltage; and
forming a first cover layer arranged on an OLED emitting light of a first wavelength, a second cover layer arranged on an OLED emitting light of a second wavelength, and a third cover layer arranged on an OLED emitting light of a third wavelength, wherein a thickness of the first cover layer, a thickness of the second cover layer, a thickness of the third cover layer are different from one another.

9. The method of claim 8, wherein the thickness of the first cover layer is equal to
$$\frac{{λ}_{1}}{4 \times Δ n ( {λ}_{1} )} ,$$
the thickness of the second cover layer is equal to
$$\frac{{λ}_{2}}{4 \times Δ n ( {λ}_{2} )} ,$$
and the thickness of the third cover layer is equal to
$$\frac{{λ}_{3}}{4 \times Δ n ( {λ}_{2} )} ,$$
where λ₁ indicates the first wavelength, λ₂ indicates the second wavelength, λ₃ indicates the third wavelength, Δn(λ₁) indicates a birefringence of the light of the first wavelength λ₁ passing through the first cover layer, Δn(λ₂) indicates a birefringence of the light of the second wavelength λ₂ passing through the second cover layer, and Δn(λ₃) indicates a birefringence of the light of the third wavelengths λ₃ passing through the third cover layer.

10. The method of claim 8, wherein the step of forming a first cover layer arranged on an OLED emitting light of a first wavelength, a second cover layer arranged on an OLED emitting light of a second wavelength, and a third cover layer arranged on an OLED emitting light of a third wavelength, comprises a step of:
depositing the first cover layer arranged on the OLED emitting light of the first wavelength, the second cover layer arranged on the OLED emitting light of the second wavelength, and the third cover layer arranged on the OLED emitting light of the third wavelength, by thermal evaporation, sputtering, inkjet printing, or chemical vapor deposition.
